(19) United States
(12) Patent Application Publication
(10) Pub. No.: US 2013/0170118 A1
(43) Pub. Date: Jul. 4, 2013

(54) ELECTRONIC DEVICE ENCLOSURE

(71) Applicant: XIU-QUAN HU, Shenzhen City (CN)

(72) Inventor: XIU-QUAN HU, Shenzhen City (CN)

(21) Appl. No.: 13/650,281

(22) Filed: Oct. 12, 2012

(30) Foreign Application Priority Data
Dec. 28, 2011 (CN) 201110446805.5

(51) Int. Cl. H05K 5/03

(52) U.S. Cl. 361/679.02

(57) ABSTRACT

An electronic device enclosure includes a chassis and a cover. The chassis defines two through holes and a receiving space configured to receive a power supply. The cover includes two latching portions. Each of the two latching portions is engaged in each of the through holes to engage the cover with the chassis, and the cover is configured to cover the receiving space when no power supply is received in the receiving space.

### BACKGROUND

1. Technical Field

The present disclosure relates to electronic device enclosures, more particularly to an electronic device enclosure with a cover.

2. Description of Related Art

A server system usually includes a chassis, and the chassis may provide a receiving room for receiving a plurality of power supplies. The number of the power supplies may be different according to different configurations of the server systems. When one of the plurality of power supplies is removed or maintained, or the chassis is not full of the plurality of power supplies, the server system dissipation stability may be influenced.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of an embodiment of an electronic device enclosure.

FIG. 2 is an exploded, cutaway view of a cover of FIG. 1.

FIG. 3 is similar to FIG. 2, but viewed from a different aspect.

FIG. 4 is an assembled view of the electronic device enclosure of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

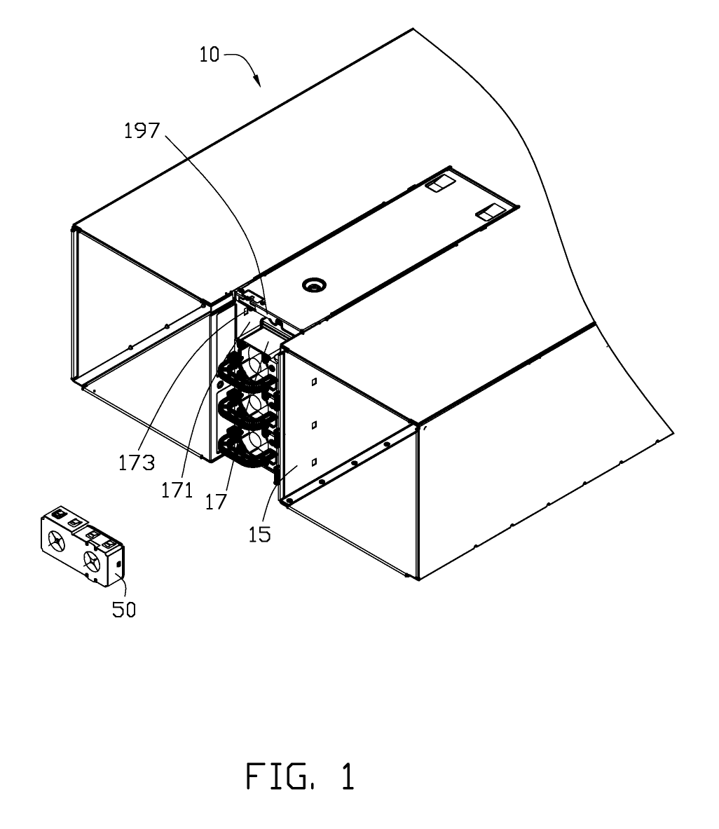

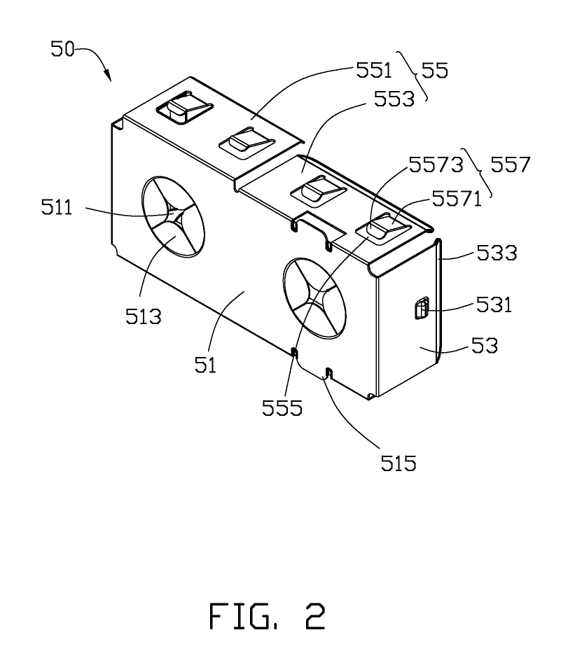

FIGS. 1 and 2 illustrates an electronic device enclosure in accordance with an embodiment. The electronic device enclosure includes a chassis 10 and a cover 50. In one embodiment, the electronic device is a server system.

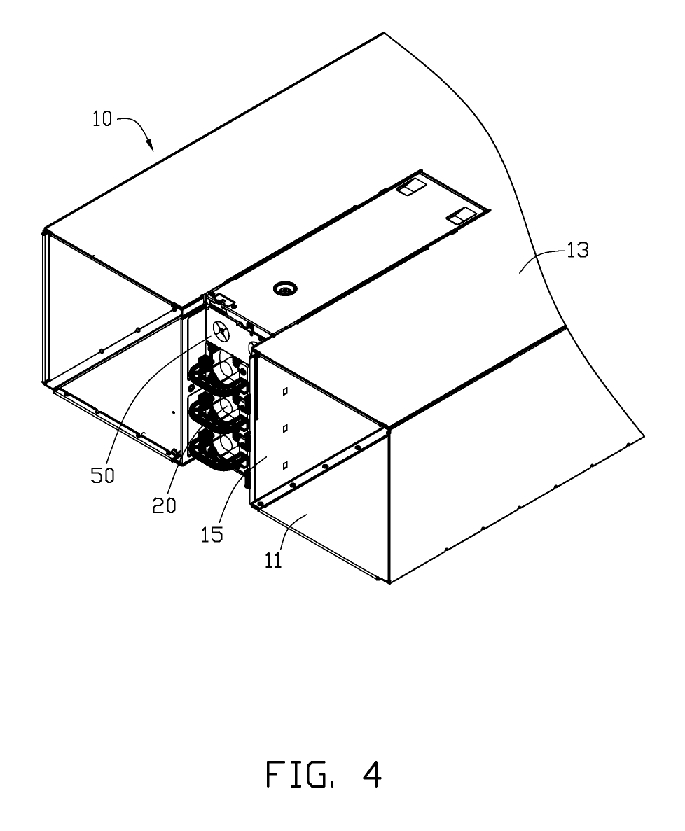

The chassis 10 includes a bottom plate 11, a top plate 13, two clipping plates 15. The bottom plate 11 is substantially parallel to the top plate 13. The two clipping plates 15 are substantially parallel to each other and perpendicularly connected to the bottom plate 11 and the top plate 13. The rear plate substantially connects to the two clipping plates 15. The two clipping plates 15, the bottom plate 11, and the top plate 13 cooperatively define a receiving room for receiving power supplies 20. A plurality of dividing plates 17 are located between the two clipping plates 15 to divide the receiving room into a plurality of receiving spaces 171. Each receiving space 171 is configured to receive one of the power supply 20 (shown in FIG. 4) or the cover 50. A through hole 173 is defined in each of the two clipping plates 15 corresponding to each receiving space 171.

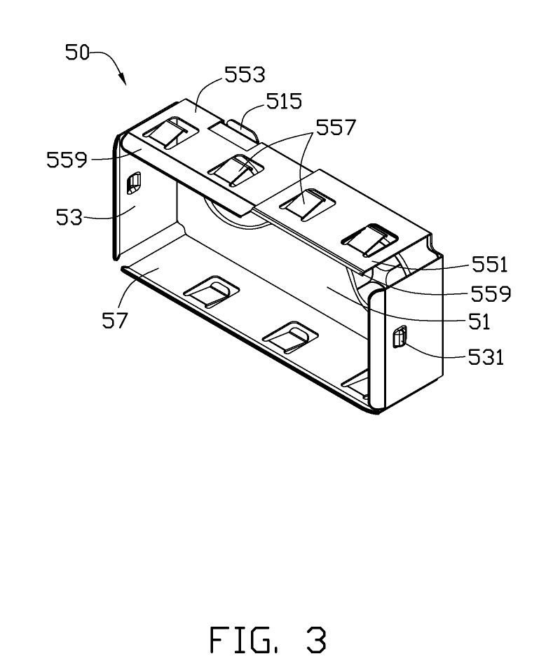

Referring to FIGS. 2 and 3, the cover 50 includes a blocking plate 51, two securing walls 53, a top wall 55, and a bottom wall 57. The blocking plate 51 defines two clipping holes 511. In one embodiment, the blocking plate is substantially rectangular. Two groups of resilient assemblies are attached on the blocking plate 51. In one embodiment, each of the two groups of resilient assemblies includes four resilient tabs 513, and the four resilient tabs 513 cooperatively define one clipping hole 511. Two stopping tabs 515 extend from the blocking plate 51 towards opposite directions and are in a same plane with the blocking plate 51. The two securing walls 53 extend from two opposite edges of the blocking plate 51 towards the chassis 10. The two securing walls 53 are substantially parallel to each other and perpendicular to the blocking plate 51. A latching portion 531 protrudes from each of the two securing wall 53 and is configured to be engaged in the through hole 173, of the two clipping plates 15. The latching portion 531 is tapered. Two first guiding pieces 533 extend towards each other from the two securing walls 53 respectively. An obtuse angle is defined between each of the two first guiding pieces 533 and each of the two securing walls 53.

The top wall 55 and the bottom wall 57 extend from other opposite edges of the blocking plate 51. A height between the top wall 55 and the bottom wall 57 is substantially equal to a height between two opposite walls of the receiving space 171. In one embodiment, the top wall 55 includes a first plate 551 and a second plate 553. Each of the top wall 55 and the bottom wall 57 define a plurality of openings 555. A plurality of resilient pieces 557 are located on the top wall 55 and the bottom wall 57 respectively. Each of the resilient pieces 557 includes a resilient portion 5571 and an end portion 5573 extending from the resilient portion 5571. The resilient portion 5571 extends obliquely from an edge of the corresponding opening 555 and has an extension direction towards the blocking plate 51. An acute angle is defined between the resilient portion 5571 and the top wall 55 and defined between the resilient portion 5571 and the bottom wall 57. The end portion 5573 extends towards the top wall 55 and the bottom wall 57 from the resilient portion 5571. Two guiding pieces 559 extend towards each other from the top wall 55 and the bottom wall 57 respectively.

Referring to FIG. 4, when the power supply 20 is not received in the receiving space 171, two fingers of an user can be inserted into the clipping holes 511 to bias the cover 50 abutting the chassis 10 and aligning with the receiving space 171. The cover 50 is pushed into the receiving space 171 along the guiding piece first 533 and the two second guiding pieces 559 to deform the latching portion 531, until the latching portion 531 aligns with the through hole 173, and then be engaged into the through hole 173. The plurality of resilient pieces 557 resiliently abut two opposite walls of the receiving space 171, to shield electromagnetic interference.

To install the power supply 20 in the receiving space 171 of the chassis 10, two fingers of the user can be inserted into the clipping holes 511 to bias the cover 50. The cover 50 can move along a second direction opposite to the first direction, and the latching portion 531 is resiliently deformed. The latching portion 531 is disengaged from the through hole 173. The cover 50 is thereby detached from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure comprising:
a chassis, the chassis defines two through holes and a receiving space configured to receive a power supply; and
a cover, the cover comprises two latching portions;
wherein each of the two latching portions is engaged in each of the through holes to engage the cover with the chassis, and the cover covers the receiving space when no power supply is received in the receiving space.

2. The electronic device enclosure of claim 1, wherein the cover further comprises a blocking plate, and the blocking plate defines two clipping holes.

3. The electronic device enclosure of claim 2, wherein the cover comprises two stopping tabs extending from the blocking plate, and the two stopping tabs abut opposite edges of the receiving space.

4. The electronic device enclosure of claim 3, wherein the two stopping tabs are coplanar with the blocking plate.

5. The electronic device enclosure of claim 2, wherein the cover further comprises a top wall and a bottom wall located on opposite sides of the blocking plate, and a height between the top wall and the bottom wall is substantially equal to between two opposite walls of the receiving space.

6. The electronic device enclosure of claim 5, wherein a plurality of resilient pieces are located on the top wall and the bottom wall, and the plurality of resilient pieces elastically abuts the two opposite walls of the receiving space.

7. The electronic device enclosure of claim 6, wherein the top wall and the bottom wall respectively define a plurality of openings according to the plurality of resilient pieces, and the each of the plurality of resilient pieces is received in each of the plurality of openings when the cover is received in the receiving space.

8. The electronic device enclosure of claim 7, wherein each of the plurality of resilient pieces extends from an edge of each of the plurality of openings, and an acute angle is defined between the resilient piece and the top wall, the bottom wall.

9. The electronic device enclosure of claim 2, wherein the cover further comprises four resilient tabs located on the blocking plate, and the four resilient tabs cooperatively define each of the two clipping holes.

10. The electronic device enclosure of claim 1, wherein the cover further comprises two securing plates, each of the two latching portions is located on each of the two securing plates; and the chassis comprises two clipping plates, and each of the through holes is defined in each of the two clipping plates.

11. The electronic device enclosure of claim 1, wherein each of the latching portions is tapered.

12. An electronic device enclosure comprising:
a chassis, the chassis comprising a top plate, two clipping plates and a dividing plate;
the top plate, the two clipping plates and the dividing plate cooperatively defining a receiving space configured to receive a power supply, and a through hole being defined in each of the two clipping plates; and
a cover, the cover comprising two latching portions,
wherein each of the two latching portions is engaged in each of the through holes to engage the cover with the chassis, and the cover is configured to cover the receiving space when no power supply is received in the receiving space.

13. The electronic device enclosure of claim 12, wherein the cover further comprises a blocking plate configured to cover the receiving space, and the blocking plate defines two clipping holes for two fingers insertion.

14. The electronic device enclosure of claim 13, wherein the cover comprises two stopping tabs extend from the blocking plate, and the two stopping tabs abut opposite edges of the receiving space.

15. The electronic device enclosure of claim 14, wherein the two stopping tabs are in a same plane with the blocking plate.

16. The electronic device enclosure of claim 13, wherein the cover further comprises a top wall and a bottom wall located on the blocking plate, and a height between the top wall and the bottom wall is substantially equal to a height between two opposite walls of the receiving space.

17. The electronic device enclosure of claim 16, wherein a plurality of resilient pieces are located on the top wall and the bottom wall, and the resilient pieces are elastically abuts walls of the receiving space.

18. The electronic device enclosure of claim 17, wherein the top wall and the bottom wall respectively define a plurality of openings according to each resilient piece, and each of the plurality of the resilient pieces is received in each of the plurality of the openings when the cover is received in the receiving space.

19. The electronic device enclosure of claim 18, wherein each resilient piece extends from an edge of each of the plurality of openings, and an acute angle is defined between the resilient piece and the top wall or the bottom wall.

20. The electronic device enclosure of claim 12, wherein the cover further comprises two securing plates, each of the two latching portions is located on each of the two securing plates; and each of the through holes is defined in each of the two clipping plates.
